(19) United States
(12) Patent Application Publication
(10) Pub. No.: US 2024/0030818 A1
(43) Pub. Date: Jan. 25, 2024

(54) DC-DC STEP UP CONVERTER SYSTEMS AND METHODS

(71) Applicant: Tiger Tool International Incorporated, Abbotsford (CA)

(72) Inventors: Michael Andrews, Bellingham, WA (US); Wilson He, Surrey (CA)

(73) Assignee: Tiger Tool International Incorporated, Abbotsford, BC (CA)

(21) Appl. No.: 18/481,953

(22) Filed: Oct. 5, 2023

Related U.S. Application Data
(63) Continuation of application No. 18/147,326, filed on Dec. 28, 2022, now abandoned.
Application No. 18/147,326 is a continuation of application No. 17/105,244, filed on Nov. 25, 2020, now abandoned.
(60) Provisional application No. 62/945,737, filed on Dec. 9, 2019.
(60) Provisional application No. 62/941,554, filed on Nov. 27, 2019.

(51) Int. Cl. H02M 3/158; H05K 1/02; H05K 1/18; B60H 1/00

(52) U.S. Cl. CPC H02M 3/158; H05K 1/0298; H05K 1/181; B60H 1/00428; B60L 2210/14; H05K 2201/093; H02M 1/0003

(57) ABSTRACT

The present invention may be embodied as a DC-DC step-up converter assembly comprising a multiple-layer PCB and a converter circuit. The converter circuit comprising a boost controller, an inductor, a capacitor, and a resistor. The boost controller, inductor, capacitor, and resistor are all supported on one side of the multiple-layer PCB. The boost controller, inductor, capacitor, and resistor are configured to operate at a switching frequency of substantially between 50 kHz and 800 kHz

### RELATED APPLICATIONS

This application (Attorney's Ref. No. P220454) is a continuation application of U.S. patent application Ser. No. 18/147,326 filed Dec. 28, 2022, currently pending.

U.S patent application Ser. No. 18/147,326 is a continuation of U.S. patent application Ser. No. 17/105,244 filed Nov. 25, 2020, now abandoned.

U.S. patent application Ser. No. 17/105,244 claims benefit of U.S. Provisional Application Ser. No. 62/941,554 filed Nov. 27, 2019, now expired.

U.S. Patent Application Ser. No. 17/105,244 also claims benefit of U.S. Provisional Application Ser. No. 62/945,737 filed Dec. 9, 2019, now expired.

The contents of all related applications are incorporated herein by reference.

### TECHNICAL FIELD

The present invention relates to DC-DC converter systems and methods and, in particular, to DC-DC step-up converters configured to operate in environments in which dissipation of heat is difficult and radio frequency interference (RFI) may be problematic.

### BACKGROUND

Vehicles such as long-haul trucks are equipped with heating and air conditioning (HVAC) systems that typically run on 24V DC. For operator comfort, such vehicle HVAC systems must be powered when the vehicle is parked. Although such equipment may run on direct current provided by an engine mounted alternator, anti-idling laws now prohibit the truck engine from constantly running when the vehicle is parked.

To allow the vehicle HVAC system to operate when the vehicle engine is not running (e.g., when the vehicle is parked), DC-DC step-up converters employing high-frequency power conversion circuits may be used. DC-DC step-up converter topologies typically employ high-frequency switching and inductors, transformers, and capacitors to smooth out switching noise into a regulated DC output voltage suitable for use by the HVAC system. In automotive and truck applications, where a battery provides a DC power source having an unregulated voltage of approximately 12 Volts, a DC-DC converter receives the unregulated 12 Volts DC as an input and provides a regulated 24 Volts DC output voltage to drive the electronic power and control circuitry of the HVAC system.

The switching techniques implemented by conventional DC-DC step-up converter topologies convert one DC voltage level to another by storing the input energy temporarily in capacitors and then releasing that energy to the output at a different voltage. Switching converters are electronically complex and operate at relative high frequencies. Like all high-frequency circuits, their components must be carefully specified and physically arranged to achieve stable operation and maintain switching noise RFI and electromagnetic interference (EMI) at acceptable levels.

An example conventional DC-DC step-up converter is the Linear Technology LTC 3787 six-layer, 2-phase step-up converter rated for 15 Amps. When configured to supply power to a conventional vehicle HVAC system, excessive heat was generated in the coils, and the maximum current rating was insufficient. Further, the conventional printed circuit board (PCB) layout from the manufacturer was inadequate for use with a vehicle HVAC system because it introduced large parasitic capacitance and inductance, leading to high output ripple, poor output voltage regulation and current limit accuracy, and high EMI issues. Accordingly, the manufacturer specified that a 12 phase board would be required to obtain a 60 Amp output appropriate for supplying power to a vehicle HVAC system operating at 24 Volts DC.

Conventional analog step-up DC voltage converters operating in the 12-24V range thus generate excessive heat when used to power a conventional vehicle HVAC system. In particular, the battery (input) voltage typically starts at 12.7V but slowly drops during the conversion stages such that the current flowing through the converter increases to levels that result in excessive heat dissipation that can result in melted wires and premature component failures. Further, excessive heat dissipation causes the efficiency of such conventional DC-DC step-up converters drops from approximately 86% to within range of approximately 50-60%. Fans may be used to cool the components of a conventional DC-DC step-up converter in some operating environments, but an HVAC system configured for use on a vehicle is a typically arranged within sealed, water-resistant enclosure that cannot accommodate the use of conventional cooling fans. The sealed enclosure not only precludes the use of fans but inhibits dissipation of heat such that problems with handling excess heating arising from high currents within conventional DC-DC step-up converters is exacerbated.

The topologies of conventional DC-DC step-up converters typically generate powerful electromagnetic radiation, often referred to as radio frequency interference (RFI), which may affect other electrical or communications equipment within the local area surrounding the converter. Vehicle HVAC compressors typically require in the nature of 40 Amps, and digital converters are typically rated for 10 Amps and cannot be easily scaled up to 40 Amps due to increase electrical noise and resulting RFI.

The need thus exists for DC-DC step-up converters that can maintain substantially constant output voltage with changing input voltages (e.g., decreasing battery system voltages), maintain high output currents, and substantially avoid overheating and RFI issues.

### SUMMARY

The present invention may be embodied as a DC-DC step-up converter assembly comprising a multiple-layer PCB, and a converter circuit comprising a boost controller, an inductor, a capacitor, and a resistor. The boost controller, inductor, capacitor, and resistor are all supported on one side of the multiple-layer PCB. The boost controller, inductor, capacitor, and resistor are configured to operate at a switching frequency of substantially between 50 kHz and 800 kHz.

The present invention may also be embodied as a charger comprising a DC-DC step-up converter assembly comprising a multiple-layer PCB and a converter circuit comprising a boost controller, an inductor, a capacitor, and a resistor. The boost controller, inductor, capacitor, and resistor are all supported on one side of the multiple-layer PCB. The boost controller, inductor, capacitor, and resistor are configured to operate at a switching frequency of substantially between 50 kHz and 800 kHz.

The present invention may also be embodied as a method of stepping up a first DC voltage to a second DC voltage comprising the following steps. A multiple-layer PCB is provided. A converter circuit comprising a boost controller, an inductor, a capacitor, and a resistor is provided. The boost controller, inductor, capacitor, and resistor are all supported on one side of the multiple-layer PCB. The boost controller, inductor, capacitor, and resistor are operated at a switching frequency of substantially between 50 kHz and 800 kHz.

### BRIEF DESCRIPTION OF THE DRAWINGS

FIGS. 1A-1G contain a schematic circuit diagram of an example DC-DC step-up converter circuit of the present invention;

FIG. 2 contains a top elevation view of an example printed circuit board implementing the example DC-DC step-up converter circuit of FIG. 1;

FIG. 3 is a perspective view of an example enclosure that is used to contain the example printed circuit board of FIG. 2;

FIGS. 4A-D contain a schematic view of a converter circuit of the present invention configured to operate as a battery charger;

FIGS. 5A-5I contain a schematic view of an interface and control system for the converter circuit depicted in FIGS. 4A-D;

FIG. 6 illustrates an example waveform that may be implemented by the converter circuit of FIGS. 4 and 5;

FIG. 7 is a logic flow diagram that may be implemented by the DC-DC step-up converter of FIGS. 4 and 5;

FIGS. 8A-8C illustrate simplified circuit diagrams of a DC-DC step-up converter of the present invention;

FIG. 9 illustrates an example DC-DC step-up converter of the present invention configured for 2-phase operation; and

FIG. 10 illustrates an example DC-DC step-up converter of the present invention configured for 4-phase operation.

### DETAILED DESCRIPTION

### I. Introduction

We conducted a series of iterative experiments whereby we varied the capacity and placement of the capacitors and the number of layers in the printed circuit board. We also varied the switching frequency and the number of circuit board layers.

### II. First Embodiment

A first embodiment of a DC-DC step-up converter of the invention was configured to employ a 2-layer 6-phase PCB. To accommodate the anticipated high currents, Metal Oxide Semiconductor Field Effect Transistors (MOSFETs) were employed. When the board was tested at the manufacturer's suggested frequency, the MOSFETs became excessively hot. To reduce the heat dissipated by the MOSFETs, the first converter embodiment was configured to operate at a lower frequency and with larger inductors to lower the frequency. The switching capacitors were arranged as close to the main ground as possible to mitigate noise. At a switching frequency of 300-350 kHz, only 2 phases would work together, creating a maximum of 15 amps. When the current was increased to above 15 amps, the 24 volt output would drop, and when more phases were added, the wave signal was affected by the EMI and caused disruption. It was concluded that more grounding was required.

### III. Second Embodiment

A second embodiment of a DC-DC step-up converter of the invention was configured to employ a 6-layer 6-phase PCB having two layers configured as ground layers to filter (e.g., reduce) noise and four layers configured to increase current carrying capacity. To dissipate heat, the current sensing path was improved. The current sensing capacitors employed were 10 mm by 10 mm 330 μF capacitors with a temperature rating of 125° C. The number of current sensing resistors was double to accommodate the higher current and the number of current sensing capacitors was also doubled.

When operated a switching frequency of 300-350 kHz, the two phase system topology of the second embodiment exhibited increased power handling of 45 amps for 37 minutes at 40° C. before capacitor failure. After adding 2 more phases, the internal heat generated was lower, but the capacitors still operated at their upper thermal limit. It was determined that further development was required because the circuitry was intended to be contained within an IP68 enclosure operating at 55° C.

### IV. Third Embodiment

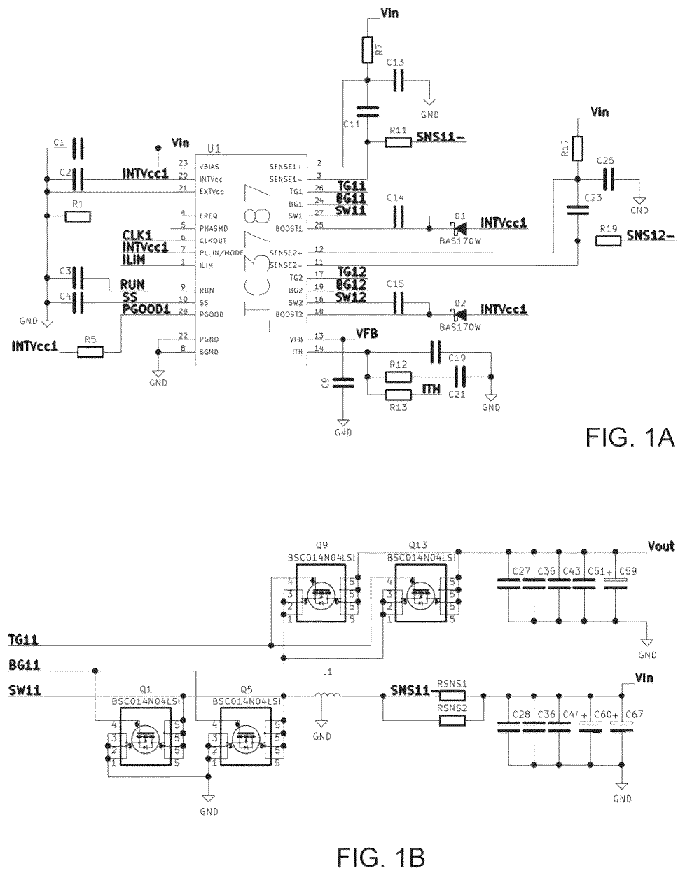

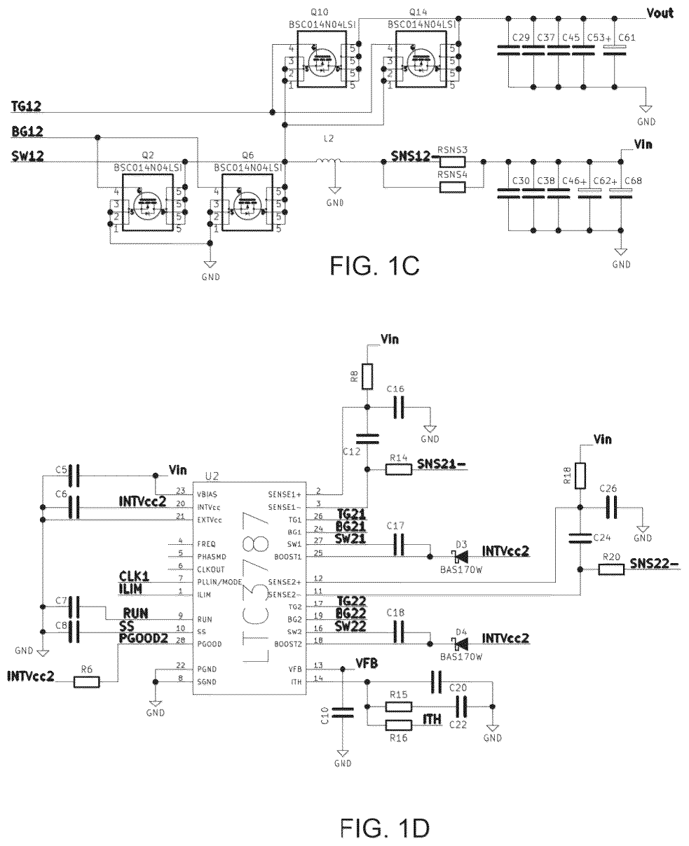

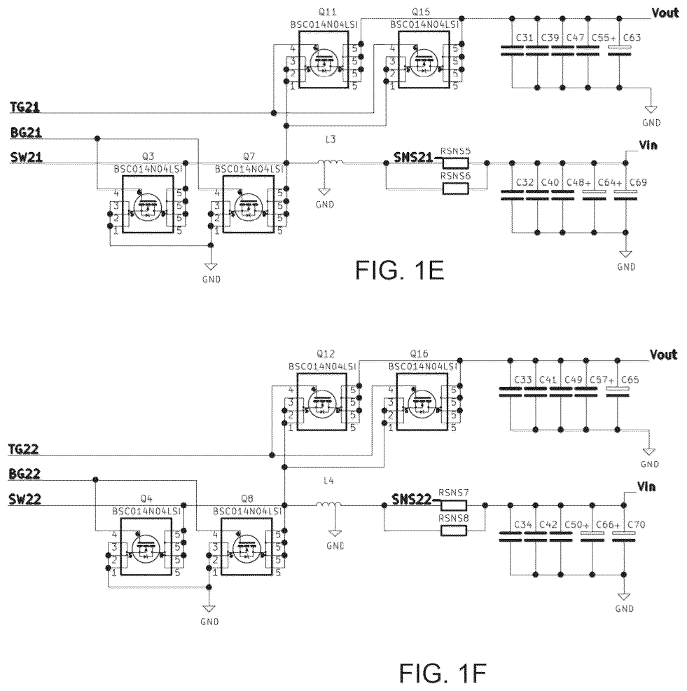

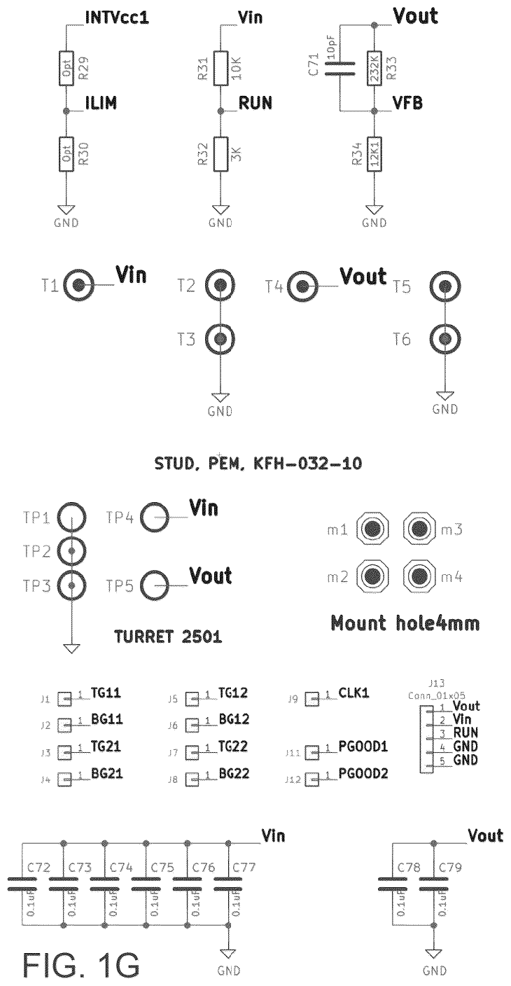

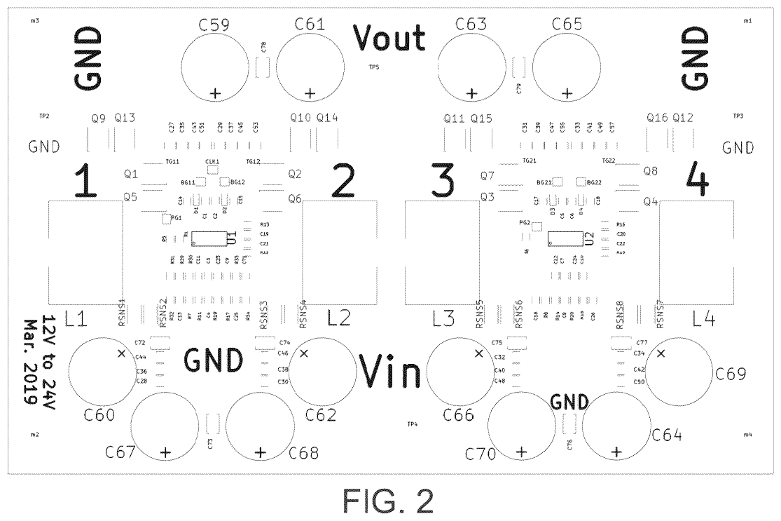

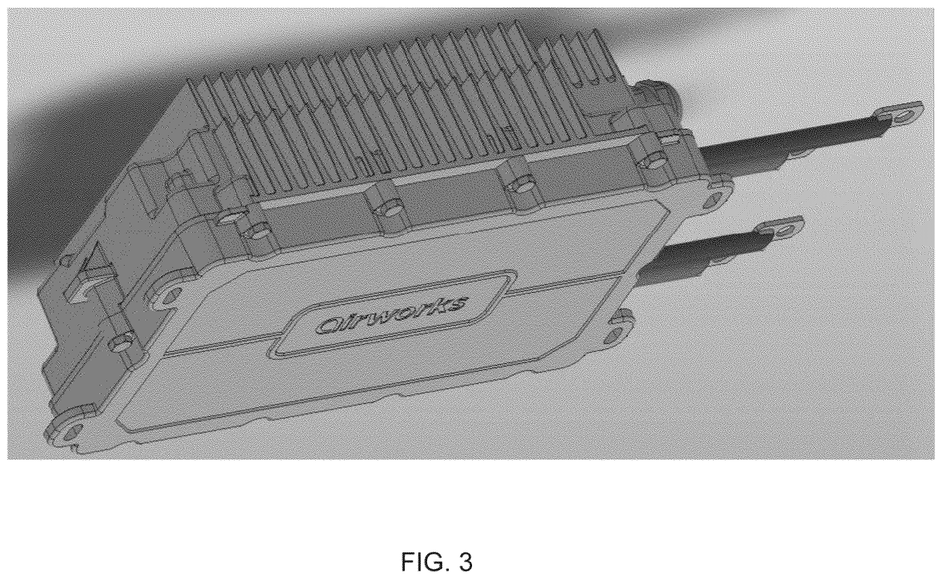

A third embodiment of a DC-DC step-up converter of the present invention employed a 6-layer, 4-phase PCB and is configured as shown in FIGS. 1 and 2. In this third embodiment, the capacitor physical size was increased to 18 mm×20 mm and value in Farads to 2700 μF with a higher operating temperature (150° C.). In addition, the resistor ratings in ohms were increased from 0.0030 Ωto 0.0060 Ω, and the circuit design layout was compressed. Contrary to conventional practice, all ICs and components were placed on the same side of the PCB instead of on different layers. The example third embodiment illustrated employs two LTC3787 polyphase synchronous boost controllers configured as shown in FIG. 1.

To test this third embodiment, the operating frequency was varied in 50 kHz (kilohertz) steps.

At 300 kHz, the third embodiment yielded an output current of 60 amps. However, the temperature of the MOSFET's reached 100° C. over ambient, temperature of the capacitors were 30° C. over ambient, and temperature of the inductor was 20° C. over ambient.

At 250 kHz, the third embodiment yielded an output current of 60 amps. However, the temperature of the MOSFET was 80° C. over ambient temperature, temperature of the capacitors 27° C. over ambient, temperature of the inductor 24° C. over ambient.

At 100 kHz, the third embodiment yielded an output current of 60 amps, and all components with acceptable temperature limits. In particular, the temperature of the MOSFET was 20° C. over ambient temperature, temperature of the capacitors 20° C. over ambient, temperature of the inductor 40° C. over ambient. However, the output voltage dropped to 23.2 V instead of the 24 V optimal for powering a vehicle HVAC system.

Still using the third embodiment, the operating frequency was increased in 10 kHz increments to correct the output voltage. At 120 kHz, the third embodiment yielded an output current of 60 amps, and the output voltage was 24.1V. Further, all components with acceptable temperature limits. In particular, the temperature of the MOSFET was 20° C. over ambient temperature, temperature of the capacitors 20° C. over ambient, temperature of the inductor 40° C. over ambient.

With a lower operating frequency and larger capacitors, the complexity of the board may be decreased such that only 4 phases are required to achieve the 60-amp at 24-volt target. The use of a lower operating frequency and larger capacitors also enhanced the longevity and stability of the board components.

Table IV-A below lists components, and variables associated with these components, may be combined to form a first embodiment of the third example DC-DC step-up converter of the present invention:

TABLE IV-A

| | | First Preferred | Second Preferred |
|---|---|---|---|
| Parameter | Example | Range | Range |
| number of layers | 6 | n/a | n/a |
| number of phases | 4 | n/a | n/a |
| inductor value (μH) | 6.8 | 5-10 | 2-20 |
| capacitor value (μF) | 2700 | 2500-3000 | 2000-3500 |
| capacitor size (mm²) | 360 | 300-500 | 200-700 |
| capacitor maximum | 150 | >125 | >100 |
| operating | | | |
| temperature (° C.) | | | |
| resistor value (Ω) | .0015 | .000005-.003 | 0.002-22. |
| sampling resistor | .0015 | .001-.003 | 0.005-0.05 |
| value (Ω) | | | |
| switching | 120 | 115-125 | 100-180 |
| frequency (kHz) | | | |

Table IV-B below lists components, and variables associated with these components, may be combined to form a second embodiment of the third example DC-DC step-up converter of the present invention:

TABLE IV-B

| | | First Preferred | Second Preferred |
|---|---|---|---|
| Parameter | Example | Range | Range |
| number of layers | 6 | 4-6 | 4-12 |
| number of phases | 4 | 2-4 | 2-12 |
| inductor value (μH) | 6.8 | 1-10 | 2-100 |
| capacitor value (μF) | 2700 | 100-3000 | 2000-7000 |
| Capacitor size DxL | 18 × 20 | .2 × 1-20 × 20 | 18 × 18-100 × 100 |
| (mm) | | | |
| capacitor size (mm²) | 360 | 1-500 | 200-700 |
| capacitor maximum | 150 | >−40 | >150 |
| operating | | | |
| temperature (° C.) | | | |
| resistor value (Ω) | .0015 | .000005-.003 | 0.002-22. |
| sampling resistor | .0015 | .001-.003 | 0.005-0.05 |
| value (Ω) | | | |
| switching frequency | 120 | 1-125 | 100-1000 |
| (kHz) | | | |

Table IV-C below lists components, and variables associated with these components, may be combined to form a third embodiment of the third example DC-DC step-up converter of the present invention:

TABLE IV-C

| | | First Preferred | Second Preferred |
|---|---|---|---|
| Parameter | Example | Range | Range |
| number of layers | 6 | 4-6 | 4-12 |
| number of phases | 4 | 2-4 | 2-12 |
| inductor value (μH) | 6.8 | 1-10 | 2-50 |
| capacitor value (μF) | 2700 | 100-1000 | 100-10000 |
| Capacitor size DxL (mm) | 18 × 20 | 16 × 20-18 × 40 | 12 × 20-18 × 40 |
| capacitor size (mm²) | 360 | 320-720 | 240-720 |
| capacitor maximum | 135 | 85-135 | 85-150 |
| operating temperature (° C.) | | | |
| resistor value (Ω) | 0.0015 | 0.0005-.003 | 0.0001-.005 |
| switching frequency (kHz) | 350 | 100-500 | 50-800 |

The third example DC-DC step-up converter described herein can further configured to step up to voltages other than 24V. In particular, the third example DC-DC step-up converter described in this Section IV can be configured to convert 12V to 36V or 48V as necessary to accommodate a particular load.

### V. Fourth Embodiment

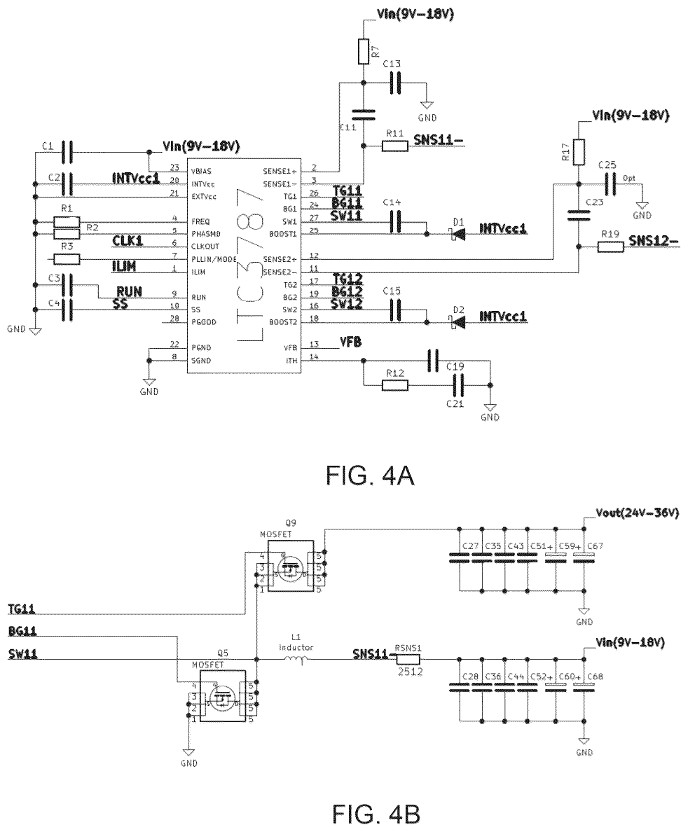

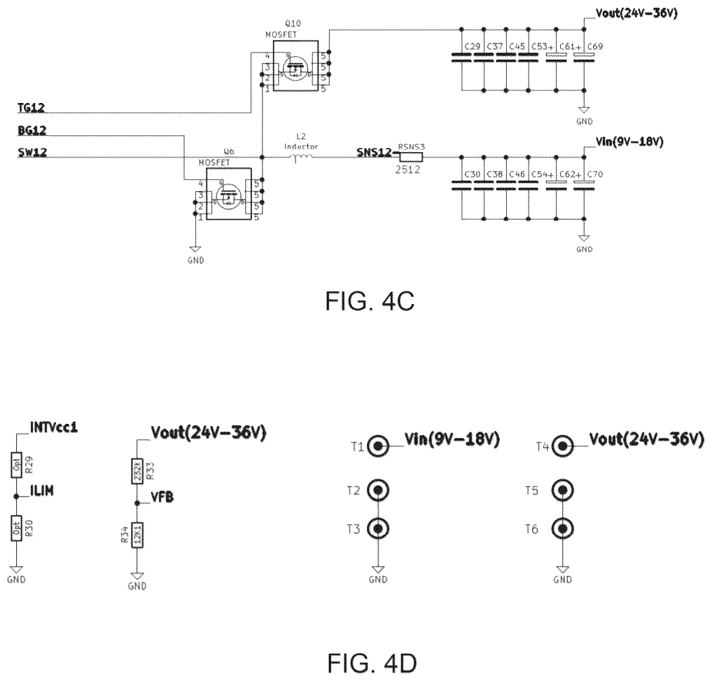

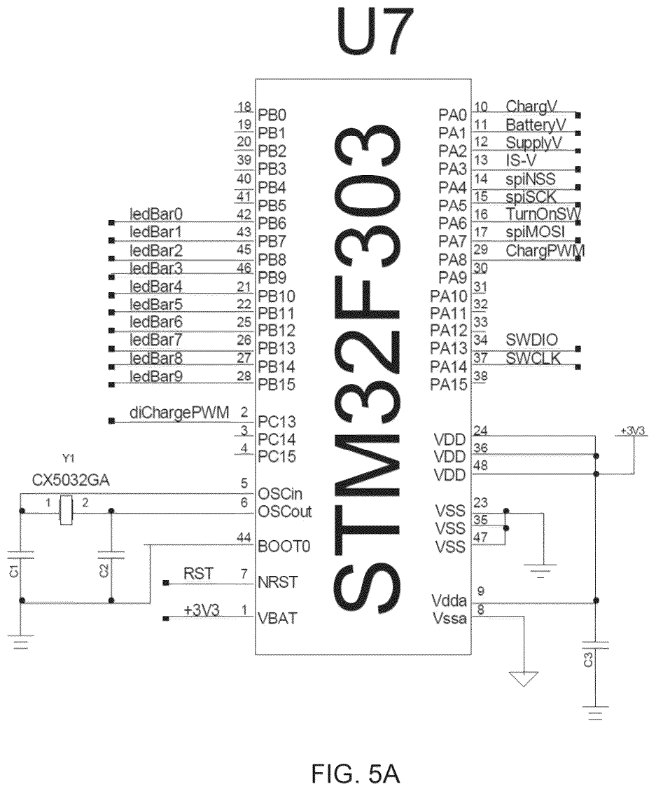

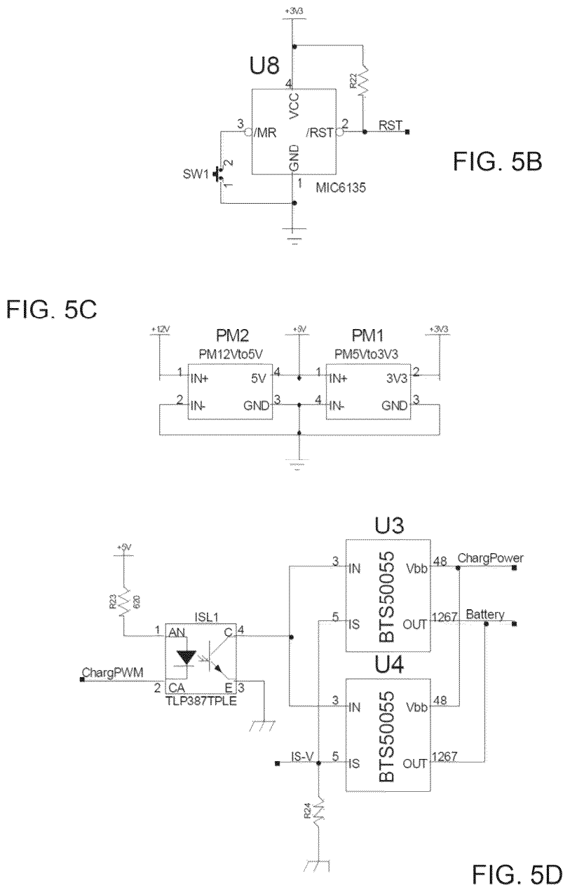

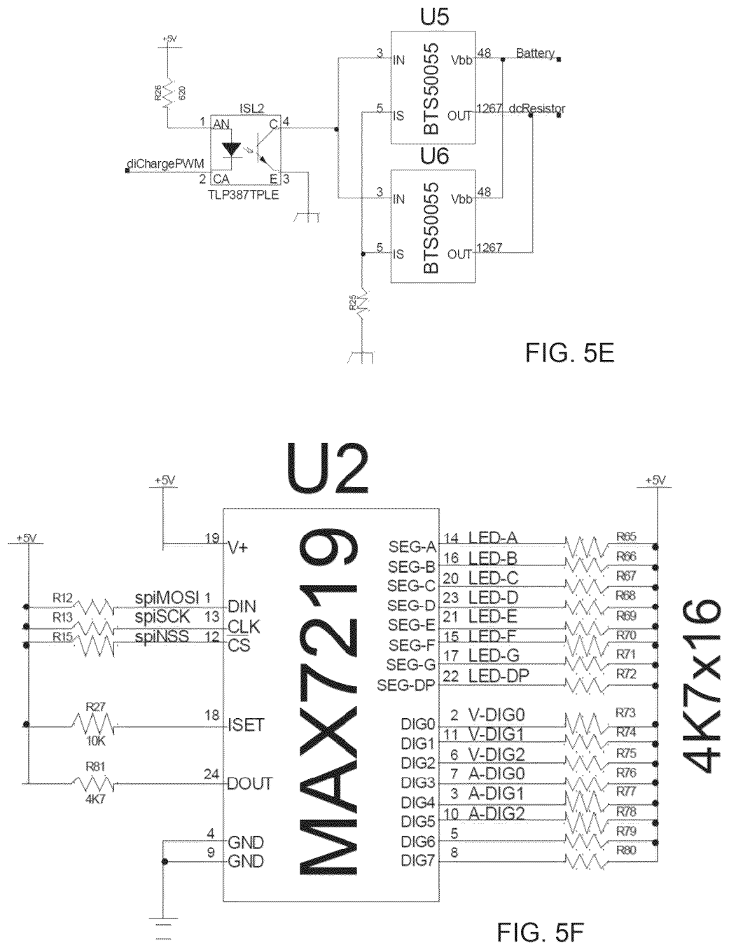

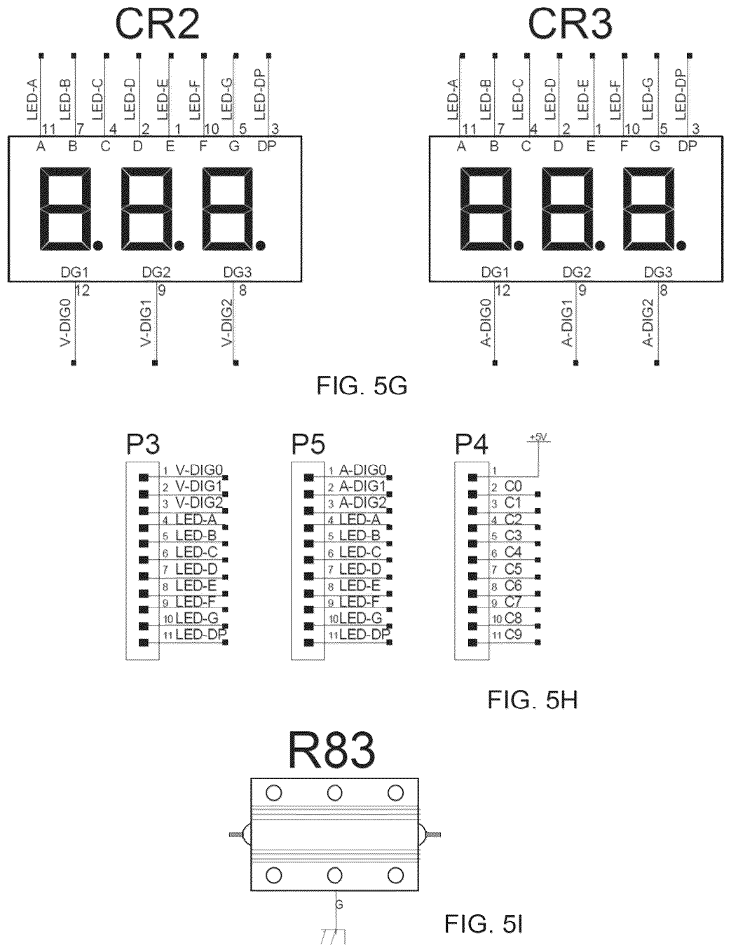

A fourth embodiment of a DC-DC step-up converter of the present invention is depicted in FIGS. 4 and 5 of the drawing. The DC-DC step-up converter of the fourth embodiment is configured to function as a battery charger but otherwise operates under principles and parameters similar to that of the third example DC-DC step-up converter depicted in FIGS. 1 and 2. Like the example third embodiment illustrated above in FIG. 2, the fourth embodiment includes at least one LTC3787 polyphase synchronous boost controller, a STM32F303 microcontroller, and a MAX7219 display driver, all of which are configured as shown in FIG. 4.

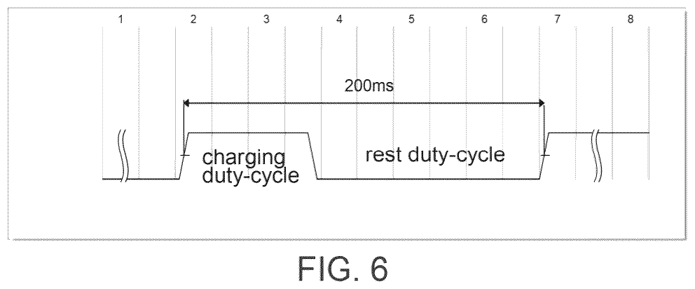

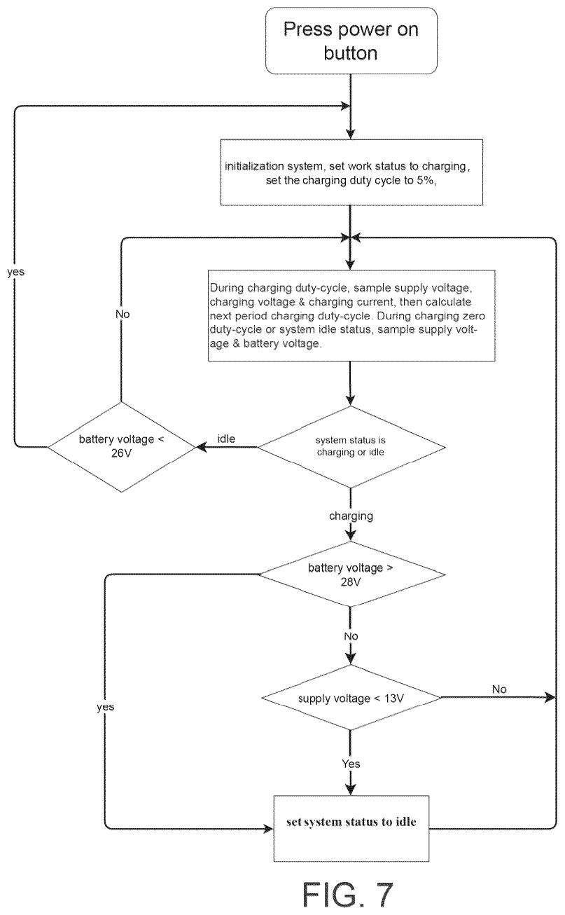

FIG. 6 illustrates a waveform that may be implemented by the DC-DC step-up converter of FIGS. 4 and 5 when configured as a battery charger. FIG. 7 illustrates a logic flow diagram that may be implemented by the DC-DC step-up converter of FIGS. 4 and 5 when configured as a battery charger. In the example waveform depicted in FIG. 6, the duty-cycle varies from 5% to 90% of the total charging period, the example charging period in FIG. 6 is 200 ms.

FIGS. 6 and 7 illustrate that battery charging may controlled during charging by altering duty cycle of the converter based on factors such as supply voltage, charge voltage, and charge current. In a rest mode, supply voltage and battery voltage are measured to determine whether to continue charging or to place the DC-DC step-up converter in an idle mode in which battery charging is discontinued. During idle mode, the supply voltage and the battery voltage may be sampled to determine whether to place the DC-DC step-up converter back into charge mode. In the example depicted in FIGS. 6 and 7, the battery charging voltage is predetermined to be substantially between 26V and 28V.

### VI. Converter Simplified Diagrams

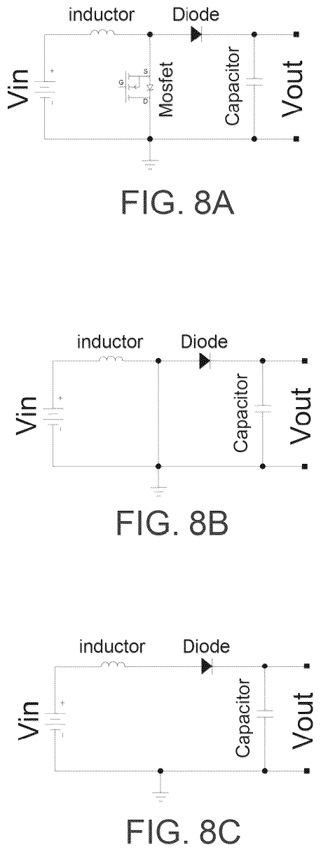

FIGS. 8A-8C illustrate simplified circuit diagrams of the example DC-DC step-up converters described above. The MOSFET depicted in FIG. 8A is switched at a predetermined frequency such that the circuit is configured in a charge phase as illustrated in FIG. 8B and a discharge phase as illustrated in FIG. 8C.

Table VI-A below lists a first example of components, and variables associated with the components, of the DC-DC step-up converter of FIGS. 8A-8C when configured according to the principles of the present invention:

TABLE VI-A

| | | First Preferred | Second Preferred |
|---|---|---|---|
| Parameter | Example | Range | Range |
| inductor value (μH) | 6.8 | 1-10 | 2-100 |
| capacitor value (μF) | 2700 | 100-3000 | 2000-7000 |
| capacitor size DxL | 18 × 20 | .2 × 1-20 × 20 | 18 × 18-100 ×100 |
| (mm) | | | |
| capacitor size (mm²) | 360 | 1-500 | 200-700 |
| capacitor maximum | 150 | >−40 | >150 |
| operating | | | |
| temperature (° C.) | | | |
| resistor value (Ω) | .0015 | .000005-.003 | 0.002-22. |
| switching frequency | 120 | 100-125 | 100-1000 |
| (kHz) | | | |

Table VI-B below lists a second example of components, and variables associated with the components, of the DC-DC step-up converter of FIGS. 8A-8C when configured according to the principles of the present invention:

TABLE IV-B

| | | First Preferred | Second Preferred |
|---|---|---|---|
| Parameter | Example | Range | Range |
| inductor value (μH) | 6.8 | 1-10 | 2-50 |
| capacitor value (μF) | 2700 | 100-3000 | 100-10000 |
| capacitor size DxL (mm) | 18 × 20 | 16 × 20-18 × 40 | 12 × 20-18 × 40 |
| capacitor size (mm²) | 360 | 320-720 | 240-720 |
| capacitor maximum | 135 | 85-135 | 85-150 |
| operating temperature (° C.) | | | |
| resistor value (Ω) | 0.0015 | 0.0005-.003 | 0.0001-.005 |
| switching frequency (kHz) | 350 | 100-500 | 50-800 |

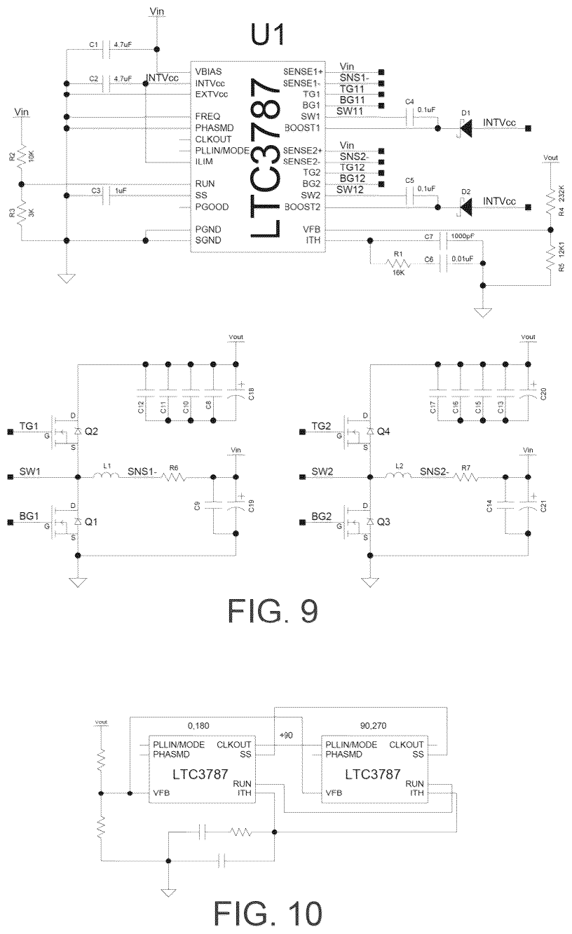

FIGS. 9 and 10 illustrate simplified circuit diagrams of DC-DC step-up converters of the present invention configured for 2-phase operation (FIGS. 9) and 4-phase operation (FIG. 10). The components of the DC-DC step-up converters of FIGS. 9 and 10, and variables associated with those components, may be the same as the examples listed in Tables IV-A and IV-B above.

What is claimed is:

1. A DC-DC step-up converter assembly comprising:
a multiple-layer PCB;
a converter circuit comprising a boost controller, an inductor, a capacitor, and a resistor; wherein
the boost controller, inductor, capacitor, and resistor are all supported on one side of the multiple-layer PCB; and
the boost controller, inductor, capacitor, and resistor are configured to operate at a switching frequency of substantially between 50 kHz and 800 kHz; wherein
the converter circuit comprises between 2 and 12 phases;
the multiple-layer PCB comprises between 4 and 12 layers; and
at least two layers of the multiple layer PCB are grounding layers.

2. A DC-DC step-up converter assembly as recited in claim 1, in which the switching frequency is substantially between 100 and 500 kHz.

3. A DC-DC step-up converter assembly as recited in claim 1, in which the switching frequency is substantially between 100 and 180 kHz.

4. A DC-DC step-up converter assembly as recited in claim 1, in which the switching frequency is substantially between 115 and 120 kHz.

5. A DC-DC step-up converter assembly as recited in claim 1, in which the multiple-layer PCB comprises between 4 and 6 layers.

6. A DC-DC step-up converter assembly as recited in claim 1, in which the converter circuit comprises between 2 and 4 phases.

7. A DC-DC step-up converter assembly as recited in claim 1, in which:
the inductor defines an inductor value of 2-100 microhenries,
the capacitor defines a capacitor value of 2000-7000 microfarads, and
the resistor defines a resistor value of 0.002-22 ohms.

8. A DC-DC step-up converter assembly as recited in claim 1, in which:
the inductor defines an inductor value of 1-10 microhenries,
the capacitor defines a capacitor value of 100-300 microfarads, and
the resistor defines a resistor value of 0.000005-0.003 ohms.

9. A DC-DC step-up converter assembly as recited in claim 1, in which:
the inductor defines an inductor value of 2-50 microhenries,
the capacitor defines a capacitor value of 100-10000 microfarads, and
the resistor defines a resistor value of 0.0001-0.005 ohms.

10. A charger comprising:
a DC-DC step-up converter assembly comprising:
a multiple-layer PCB;
a converter circuit comprising a boost controller, an inductor, a capacitor, and a resistor; wherein
the boost controller, inductor, capacitor, and resistor are all supported on one side of the multiple-layer PCB; and
the boost controller, inductor, capacitor, and resistor are configured to operate at a switching frequency of substantially between 50 kHz and 800 kHz; wherein
the converter circuit comprises between 2 and 12 phases;
the multiple-layer PCB comprises between 4 and 12 layers; and
at least two layers of the multiple layer PCB are grounding layers.

11. A charger as recited in claim 10, in which the switching frequency is substantially between 100 and 500 kHz.

12. A charger as recited in claim 10, in which the multiple-layer PCB comprises between 4 and 12 layers.

13. A charger as recited in claim 10, in which:
the inductor defines an inductor value of 2-50 microhenries,
the capacitor defines a capacitor value of 100-10000 microfarads, and
the resistor defines a resistor value of 0.0001-0.005 ohms.

14. A method of stepping up a first DC voltage to a second DC voltage comprising the steps of:
providing a multiple-layer PCB comprising between 4 and 12 layers, where at least two layers of the multiple layer PCB are grounding layers;
providing a converter circuit comprising a boost controller, an inductor, a capacitor, and a resistor, where the converter circuit comprises between 2 and 12 phases;
supporting the boost controller, inductor, capacitor, and resistor all on one side of the multiple-layer PCB; and
operating the boost controller, inductor, capacitor, and resistor at a switching frequency of substantially between 50 kHz and 800 kHz.

15. A method as recited in claim 14, in which:
the inductor defines an inductor value of 2-100 microhenries,
the capacitor defines a capacitor value of 2000-7000 microfarads, and
the resistor defines a resistor value of 0.002-22 ohms.

16. A method as recited in claim 14, in which:
the inductor defines an inductor value of 1-10 microhenries,
the capacitor defines a capacitor value of 100-300 microfarads, and
the resistor defines a resistor value of 0.000005-0.003 ohms.

17. A method as recited in claim 14, in which:
the inductor defines an inductor value of 2-50 microhenries,
the capacitor defines a capacitor value of 100-10000 microfarads, and
the resistor defines a resistor value of 0.0001-0.005 ohms.
